(19) United States
(12) Patent Application Publication
(10) Pub. No.: US 2023/0275079 A1
(43) Pub. Date: Aug. 31, 2023

(54) Layout Structure of High-Drive-Multiple Standard Cell

(71) Applicant: Shanghai Huali Integrated Circuit Corporation, Shanghai (CN)

(72) Inventor: Weihuan Gao, Shanghai (CN)

(73) Assignee: Shanghai Huali Integrated Circuit Corporation, Shanghai (CN)

(21) Appl. No.: 18/167,181

(22) Filed: Feb. 10, 2023

(30) Foreign Application Priority Data
Feb. 28, 2022 (CN) 202210205970.X

(51) Int. Cl. H01L 27/02; H01L 27/118

(52) U.S. Cl. CPC H01L 27/0207; H01L 27/11807; H01L 2027/11875; H01L 2027/11881

(57) ABSTRACT

The present application provides a layout structure of a high-drive-multiple standard cell library, a power line track disposed in the middle of a standard cell along a length direction thereof, the length of the power line track being in flush with the width of the standard cell, two ends of the power line track being respectively provided with first-layer metal wires, a length direction of the first-layer metal wires being along a length direction of the standard cell, the intermediate wiring of the power line track being realized through a metal wire other than the first-layer metal wires; ground wires located at the topmost and bottommost positions of the standard cell, the ground wires being connected to the first-layer metal wires; PMOS transistors located directly below the power line track; NMOS transistors located at upper and lower ends of the standard cell and adjacent to the ground wires.

### CROSS-REFERENCE TO RELATED APPLICATIONS

This application claims priority to Chinese patent application No. 202210205970.X, filed on Feb. 28, 2022, the disclosure of which is incorporated herein by reference in its entirety.

### TECHNICAL FIELD

The present application relates to the field of semiconductor technology, in particular to a layout structure of a high-drive-multiple standard cell library.

### BACKGROUND

A power line track of the traditional high-drive-multiple standard cell is located at the topmost track of the standard cell. A ground wire is located on the bottommost track of the standard cell. PMOS transistors are located at an upper end of the standard cell, which are as close to the power line as much as possible and have a size maximized on the basis of meeting the design rules provided by the chip manufacturer. NMOS transistors are located at a lower end of the standard cell, which are close to the ground wire as much as possible and have a size maximized on the basis of meeting the design rules provided by the chip manufacturer. This method requires the area is (N*Track)*(X*Pick), where Track is the minimum distance between metal wires in a horizontal direction, N is an integral multiple of 0.5, N*Track represents the height of the standard cell, Pitch represents the minimum distance between metal wires in a vertical direction, and X is the drive multiple of the standard cell.

However, the traditional high-drive-multiple standard cell requires high driving force, and the traditional method can only increase the driving force by increasing the transverse width and adopting parallel connection, so the area will be greatly lost.

### BRIEF SUMMARY

In view of the disadvantages of the existing technology, the purpose of the present application is to provide a layout structure of a high-drive-multiple standard cell library, which is used for solving the problem that the area is greatly lost since the standard cell library in the existing technology can only increase the driving force by increasing the transverse width and adopting parallel connection.

In order to realize the above and other related purposes, the present application provides a layout structure of a high-drive-multiple standard cell library, which at least includes:
a power line track disposed in the middle of a standard cell along a length direction thereof, the length of the power line track being in flush with the width of the standard cell,
two ends of the power line track being respectively provided with first-layer metal wires, a length direction of the first-layer metal wires being along a length direction of the standard cell, the intermediate wiring of the power line track being realized through a metal wire other than the first-layer metal wires;
ground wires located at the topmost and bottommost positions of the standard cell, the ground wires being connected to the first-layer metal wires;
PMOS transistors located directly below the power line track; and
NMOS transistors located at upper and lower ends of the standard cell and adjacent to the ground wires.

Exemplarily, the first-layer metal wires are further used for splicing with other cells.

Exemplarily, a way of realizing the intermediate wiring of the power line track through a metal wire other than the first-layer metal wires includes realizing the intermediate wiring of the power line track through a metal wire above the first-layer metal wires.

Exemplarily, the intermediate wiring of the power line track is realized through a metal wire above the first-layer metal wires so that PMOS and NMOS are connected above and below the first-layer metal wires.

Exemplarily, the intermediate wiring of the power line track is realized through a metal wire above the first-layer metal wires and the metal wire is a transverse metal wire.

Exemplarily, the first-layer metal wires are connected to top-layer metal wires.

Exemplarily, the area of the standard cell is (2*N*Track)*(X*Wpmos/(2*Wpmos+Spmos)*Pitch), where Wpmos is the width of the PMOS transistor, Spmos is the spacing between the PMOS transistors, Pitch is the minimum distance between the first-layer metal wires along a transverse direction, Track is the minimum distance between the first-layer metal wires along a longitudinal direction, N is an integral multiple of 0.5, and X is the drive multiple of the standard cell.

As mentioned above, the layout structure of the high-drive-multiple standard cell library provided by the present application has the following beneficial effects: compared with the traditional layout structure of the high-drive-multiple standard cell library, the layout structure of the high-drive-multiple standard cell library provided by the present application greatly reduces the area thereof and greatly improves the driving force.

### BRIEF DESCRIPTION OF THE DRAWINGS

FIG. 1 illustrates a schematic diagram of a layout structure of a high-drive-multiple standard cell library according to the present application.

### DETAILED DESCRIPTION OF THE APPLICATION

The implementation modes of the present application will be described below through specific examples. Those skilled in the art can easily understand other advantages and effects of the present application from the content disclosed in the description. The present application can also be implemented or applied in different specific implementation modes. Various details in the description can also be modified or changed based on different views and applications without departing from the spirit of the present application.

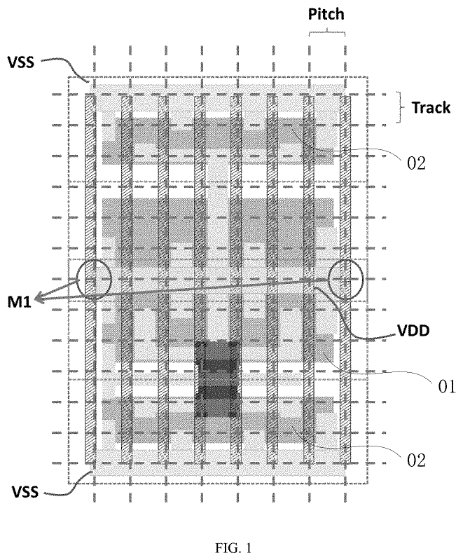

Refer to FIG. 1. It should be noted that the drawings provided in the embodiment only illustrate the basic concept of the present application in a schematic way, only illustrate the components related to the present application, and are not drawn according to the number, shape and size of the components in actual implementation. The type, number and scale of the components in actual implementation may be changed freely, and the layout of the components may be more complex.

The present application provides a layout structure of a high-drive-multiple standard cell library, which at least includes:
a power line track disposed in the middle of a standard cell along a length direction thereof, the length of the power line track being in flush with the width of the standard cell,
two ends of the power line track being respectively provided with first-layer metal wires, a length direction of the first-layer metal wires being along a length direction of the standard cell, the intermediate wiring of the power line track being realized through a metal wire other than the first-layer metal wires;
ground wires located at the topmost and bottommost positions of the standard cell, the ground wires being connected to the first-layer metal wires;
PMOS transistors located directly below the power line track; and
NMOS transistors located at upper and lower ends of the standard cell and adjacent to the ground wires.

Referring to FIG. 1, it illustrates a schematic diagram of a layout structure of a high-drive-multiple standard cell library according to the present application. The layout structure of the high-drive-multiple standard cell library at least includes:
a power line track VDD disposed in the middle of a standard cell along a length direction thereof, the length of the power line track VDD being in flush with the width of the standard cell,
two ends of the power line track VDD being respectively provided with first-layer metal wires M1, a length direction of the first-layer metal wires M1 being along a length direction of the standard cell, the intermediate wiring of the power line track VDD being realized through a metal wire other than the first-layer metal wires M1;
ground wires VSS located at the topmost and bottommost positions of the standard cell, the ground wires VSS being connected to the first-layer metal wires M1;
PMOS transistors 01 located directly below the power line track VDD; and
NMOS transistors 02 located at upper and lower ends of the standard cell and adjacent to the ground wires VSS.

Further, in this embodiment, the first-layer metal wires M1 are further used for splicing with other cells.

Further, in this embodiment, a way of realizing the intermediate wiring of the power line track through a metal wire other than the first-layer metal wires M1 includes realizing the intermediate wiring of the power line track VDD through a metal wire above the first-layer metal wires M1.

Further, in this embodiment, the intermediate wiring of the power line track VDD is realized through a metal wire above the first-layer metal wires so that PMOS and NMOS are connected above and below the first-layer metal wires.

Further, in this embodiment, the intermediate wiring of the power line track VDD is realized through a metal wire above the first-layer metal wires M1 and the metal wire is a transverse metal wire.

Further, in this embodiment, the first-layer metal wires are connected to top-layer metal wires.

Further, in this embodiment, the area of the standard cell is (2*N*Track)*(X*Wpmos/(2*Wpmos+Spmos)*Pitch), where Wpmos is the width of the PMOS transistors, Spmos is the spacing between the PMOS transistors, Pitch is the minimum distance between the first-layer metal wires along a transverse direction, Track is the minimum distance between the first-layer metal wires along a longitudinal direction, N is an integral multiple of 0.5, and X is the drive multiple of the standard cell.

To sum up, compared with the layout structure of the traditional high-drive-multiple standard cell library, the layout structure of the high-drive-multiple standard cell library provided by the present application has the advantages that the area is greatly reduced and the driving force is greatly improved. Therefore, the present application effectively overcomes various disadvantages of the existing technology and has a great industrial utilization value.

The above embodiments are only used for exemplarily describing the principle and effect of the present application, instead of limiting the present application. Those skilled in the art may modify or change the above embodiments without departing from the spirit and scope of the present application. Therefore, all equivalent modifications or changes made by those skilled in the art without departing from the spirit and technical concept disclosed by the present application shall still be covered by the claims of the present application.

What is claimed is:

1. A layout structure of a high-drive-multiple standard cell library, wherein the layout structure of the high-drive-multiple standard cell library at least comprises:
a power line track disposed in the middle of a standard cell along a length direction thereof, a length of the power line track being in flush with a width of the standard cell,
two ends of the power line track being respectively provided with first-layer metal wires, a length direction of the first-layer metal wires being along the length direction of the standard cell, an intermediate wiring of the power line track being realized through a metal wire other than the first-layer metal wires;
ground wires located at topmost and bottommost positions of the standard cell, the ground wires being connected to the first-layer metal wires;
PMOS transistors located directly below the power line track; and
NMOS transistors located at upper and lower ends of the standard cell and adjacent to the ground wires.

2. The layout structure of the high-drive-multiple standard cell library according to claim 1, wherein the first-layer metal wires are further used for splicing with other cells.

3. The layout structure of the high-drive-multiple standard cell library according to claim 1, wherein a way of realizing the intermediate wiring of the power line track through the metal wire other than the first-layer metal wires comprises realizing the intermediate wiring of the power line track through a metal wire above the first-layer metal wires.

4. The layout structure of the high-drive-multiple standard cell library according to claim 3, wherein the intermediate wiring of the power line track is realized through the metal wire above the first-layer metal wires so that PMOS and NMOS are connected above and below the first-layer metal wires.

5. The layout structure of the high-drive-multiple standard cell library according to claim 3, wherein the intermediate wiring of the power line track is realized through the metal wire above the first-layer metal wires and the metal wire is a transverse metal wire.

6. The layout structure of the high-drive-multiple standard cell library according to claim 1, wherein the first-layer metal wires are connected to top-layer metal wires.

7. The layout structure of the high-drive-multiple standard cell library according to claim 1, wherein an area of the standard cell is (2*N*Track)*(X*Wpmos/(2*Wpmos+Spmos)*Pitch), where Wpmos is a width of the PMOS transistors, Spmos is a spacing between the PMOS transistors, Pitch is a minimum distance between the first-layer metal wires along a transverse direction, Track is a minimum distance between the first-layer metal wires along a longitudinal direction, N is an integral multiple of 0.5, and X is a drive multiple of the standard cell.
